(19) United States
(12) Patent Application Publication
(10) Pub. No.: US 2024/0125835 A1
(43) Pub. Date: Apr. 18, 2024

(54) ELECTROSTATIC ELECTRICITY MITIGATION

(71) Applicant: International Business Machines Corporation, Armonk, NY (US)

(72) Inventors: John M. Ganci, JR., Raleigh, NC (US); Martin G. Keen, Cary, NC (US); Jeremy R. Fox, Georgetown, TX (US); Sarbajit K. Rakshit, Kolkata (IN)

(21) Appl. No.: 17/968,355

(22) Filed: Oct. 18, 2022

(51) Int. Cl. G01R 29/14

(52) U.S. Cl. CPC G01R 29/14

(57) ABSTRACT

Disclosed embodiments provide techniques for monitoring, detecting, predicting, and mitigating electrostatic electricity accumulation. Electrostatic electricity is detected within a premises, via multiple electrostatic electricity sensors. The electrostatic electricity sensors, also referred to as electrostatic charge sensors can detect electrostatic electricity and/or electrostatic potential. Disclosed embodiments acquire electrostatic electricity data from multiple sensors. Other mechanical activity is also acquired via sensors and/or computer vision techniques. The mechanical activity can include motion of machines and/or people. Disclosed embodiments correlate levels of electrostatic electricity data to mechanical activity using machine learning. The machine learning system is used to predict future levels of electrostatic electricity based on proposed and/or mechanical activity, as well as automatically invoke mitigation steps and generate alert messages.

### FIELD

The present invention relates generally to electricity, and more particularly, to electrostatic electricity mitigation.

### BACKGROUND

Static electricity is caused by an imbalance of electric charges on a material. Creating electrostatic charge by contact and separation of materials is known as triboelectric charging. Triboelectric charging involves the transfer of electrons between materials. The atoms of a material with no static charge have an equal number of positive (+) protons in the nucleus and negative (−) electrons orbiting the nucleus.

Static electricity is generally measured in coulombs. The charge (q) on an object can be determined by the product of the capacitance of the object (C) and the voltage potential on the object (V) by the formula q=CV. The level of charge created by triboelectric charging is a function of the area of contact, relative humidity, the chemistry of the materials, surface work function, as well as other factors. When this charge accumulates on a material, it becomes an electrostatically charged material. This charge may be transferred from the material, creating an electrostatic discharge (ESD) event, often in the form of a spark.

Electrostatic discharge (ESD) can occur when a non-conducting surface is rubbed against another and the contacted surfaces are then parted. ESD can damage or destroy sensitive electronic components, erase or alter magnetic media, and/or set off explosions or fires in flammable environments. Each year, ESD damage causes millions of dollars of inventory loss in factories and warehouses.

### SUMMARY

In one embodiment, there is provided a computer-implemented method for electrostatic electricity management within a premises, comprising: obtaining a measurement for electrostatic charge at a plurality of locations within the premises; detecting mechanical activity within the premises; and creating an electrostatic electricity temporospatial pattern (ESETP) of the premises wherein the ESETP is based on the obtained measurements and the mechanical activity.

In another embodiment, there is provided an electronic computation device comprising: a processor; a memory coupled to the processor, the memory containing instructions, that when executed by the processor, cause the electronic computation device to: obtain a measurement for electrostatic charge at a plurality of locations within a premises; detect mechanical activity within the premises; and create an electrostatic electricity temporospatial pattern (ESETP) of the premises wherein the ESETP is based on the obtained measurements and the mechanical activity.

In another embodiment, there is provided a computer program product for an electronic computation device comprising a computer readable storage medium having program instructions embodied therewith, the program instructions executable by a processor to cause the electronic computation device to: obtain a measurement for electrostatic charge at a plurality of locations within a premises; detect mechanical activity within the premises; and create an electrostatic electricity temporospatial pattern (ESETP) of the premises wherein the ESETP is based on the obtained measurements and the mechanical activity.

### BRIEF DESCRIPTION OF THE DRAWINGS

FIG. 1 is an exemplary computing environment in accordance with disclosed embodiments.

FIG. 2 is an exemplary premises utilizing embodiments of the present invention.

FIG. 3 is an exemplary ecosystem in accordance with disclosed embodiments.

FIG. 4 is an exemplary visualization map in accordance with disclosed embodiments.

FIG. 5 is an exemplary visualization map overlay in accordance with disclosed embodiments.

FIG. 6 is a flowchart indicating process steps for disclosed embodiments.

FIG. 7 is an exemplary user interface in accordance with embodiments of the present invention.

FIG. 8 shows an example of log file analysis in accordance with disclosed embodiments.

FIG. 9 is a block diagram of a sensor device in accordance with disclosed embodiments.

The drawings are not necessarily to scale. The drawings are merely representations, not necessarily intended to portray specific parameters of the invention. The drawings are intended to depict only example embodiments of the invention, and therefore should not be considered as limiting in scope. In the drawings, like numbering may represent like elements. Furthermore, certain elements in some of the Figures may be omitted, or illustrated not-to-scale, for illustrative clarity.

### DETAILED DESCRIPTION

Disclosed embodiments provide techniques for monitoring, detecting, predicting, and mitigating electrostatic electricity accumulation. Electrostatic electricity is detected within a premises, via multiple electrostatic electricity sensors. The electrostatic electricity sensors, also referred to as electrostatic charge sensors can detect electrostatic electricity and/or electrostatic potential. The sensors can be Internet-of-Things (IoT) sensors that are equipped with a wireless communication interface to facilitate frequent and convenient reading of sensor data.

In embodiments, the premises can be a factory, warehouse, processing plant, or any other location where it is desired to monitor and mitigate electrostatic electricity. Disclosed embodiments acquire electrostatic electricity data from multiple sensors. In addition to electrostatic electricity data, other mechanical activity is also acquired via sensors and/or computer vision techniques. The mechanical activity can include motion of machines and/or people. Disclosed embodiments correlate levels of electrostatic electricity data to mechanical activity. In embodiments, the correlation is performed using machine learning. The machine learning can be supervised machine learning. Once the machine learning system is trained, it can be used to predict future levels of electrostatic electricity based on proposed facility operations and/or mechanical activity.

Embodiments can further include mitigation and protection processes. Protection processes can include automatically disabling or adjusting machinery to prevent damage until the electrostatic electricity levels are reduced. Mitigation processes can include adjusting environmental factors such as temperature and/or humidity levels, and/or operation of other mitigation equipment, such as ionizing fans.

Embodiments can further include reporting and visualization processes. These can include establishing automated alerts to stakeholders, visualization maps showing areas of high electrostatic electricity and/or potential, and/or visualization map overlays. The visualization map overlays can provide a graphical representation of electrostatic electricity levels associated with various regions of a premises.

Features of disclosed embodiments include the ability to correlate electrostatic electricity levels with other conditions such as mechanical activity and/or environmental activity. As an example, a worker pushing items on a surface such as a table can generate elevated electrostatic electricity levels. By detecting the elevated electrostatic electricity levels and correlating it with the mechanical activity of pushing items on a surface, an intelligent alert is generated by systems in accordance with disclosed embodiments, that pinpoints the cause of the elevated electrostatic electricity levels, such that an appropriate mitigation action can be taken. Systems in accordance with disclosed embodiments provide procedural recommendations such as notifying the worker to stop the activity, and/or use of additional equipment, (e.g., use a handcart instead of pushing the items along a surface). Additionally, disclosed embodiments can automatically perform mitigation steps such as activation of ionizing fans or other ESD mitigation equipment to mitigate elevated electrostatic electricity levels.

Reference throughout this specification to “one embodiment,” “an embodiment,” “some embodiments”, or similar language means that a particular feature, structure, or characteristic described in connection with the embodiment is included in at least one embodiment of the present invention. Thus, appearances of the phrases “in one embodiment,” “in an embodiment,” “in some embodiments”, and similar language throughout this specification may, but do not necessarily, all refer to the same embodiment.

Moreover, the described features, structures, or characteristics of the invention may be combined in any suitable manner in one or more embodiments. It will be apparent to those skilled in the art that various modifications and variations can be made to the present invention without departing from the spirit and scope and purpose of the invention. Thus, it is intended that the present invention cover the modifications and variations of this invention provided they come within the scope of the appended claims and their equivalents. Reference will now be made in detail to the preferred embodiments of the invention.

The terminology used herein is for the purpose of describing particular embodiments only and is not intended to be limiting of this disclosure. As used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. The term “set” is intended to mean a quantity of at least one. It will be further understood that the terms “comprises” and/or “comprising”, or “includes” and/or “including”, or “has” and/or “having”, when used in this specification, specify the presence of stated features, regions, integers, steps, operations, elements, and/or components, but do not preclude the presence or addition of one or more other features, regions, or elements.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

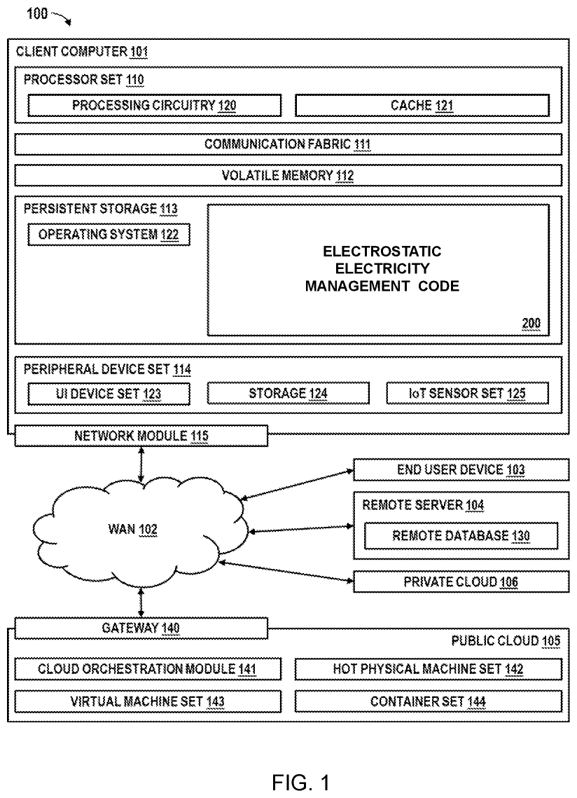

FIG. 1 shows an exemplary computing environment 100 in accordance with disclosed embodiments. Computing environment 100 contains an example of an environment for the execution of at least some of the computer code involved in performing the inventive methods, such as electrostatic electricity management code block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

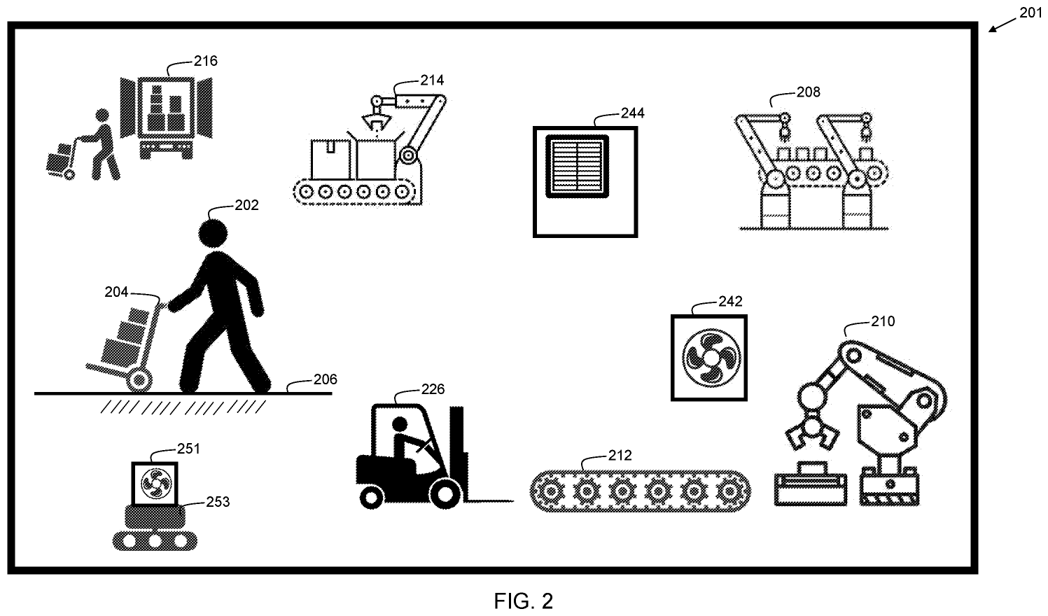

FIG. 2 is an exemplary premises 201 utilizing embodiments of the present invention. Disclosed embodiments are well-suited for factories, warehouses, and any other environment where electrostatic discharge (ESD) has the potential to cause problems. In particular, electronic devices, semiconductor integrated circuits, and magnetic media, are prone to damage from ESD. Furthermore, for warehouses, chemical plants, or any other location with flammable vapors, high levels of dust, or explosive compounds, electrostatic discharge can cause unwanted sparks that can cause serious damage.

In the exemplary premises 201, there are multiple elements, representative of things commonly found in a factory premises. At 202, there is a worker (person) walking along floor 206, pushing a cart 204. This is an example of mechanical activity. The motion of the worker along the floor can be a source of electrostatic electricity. A fabrication machine 208 is shown, which can also be a source of electrostatic electricity as materials are moved along, or rubbed against, other materials. A loading machine 210 is shown, which can also be a source of electrostatic electricity as materials are moved along, or rubbed against, other materials. A conveyor belt 212 is shown, which can also be a source of electrostatic electricity as materials are moved along, or rubbed against, other materials. A fork lift 226 is shown, which can also be a source of electrostatic electricity as materials are moved along, or rubbed against, other materials. A packaging machine 214 is shown, which can also be a source of electrostatic electricity as materials are moved along, or rubbed against, other materials. A loading area 216 is shown, where trucks may load and unload cargo, which can also be a source of electrostatic electricity as materials are moved along, or rubbed against, other materials.

The aforementioned machines are indicative of typical mechanical activity in a fabrication premises. In practice, factories have a variety of different types of equipment and associated mechanical activities. As an example, a semiconductor fabrication plant may have wafer planarization stations, lithography stations, wafer cutting stations, packaging stations, testing stations, vibration plate feeders, and so on. Similarly, an electronic device factory may have pick-and-place machines, wave solder machines, chassis assembly machines, packaging machines, labeling machines, and the like. Each of these stations, as well as the mechanical activity of workers moving items, either by hand or on motorized equipment, has the potential to generate elevated levels of electrostatic electricity. Activities such as metal cutting, dragging of material, pouring of liquid, that are common in manufacturing environments, can also be a source of elevated electrostatic electricity levels.

Premises 201 includes electrostatic energy mitigation equipment. The electrostatic energy mitigation equipment can include ionizing fan 242 and/or humidification system 244. Disclosed embodiments can automatically operate this equipment in response to detecting an elevated electrostatic level and/or predicting a future elevated electrostatic level. The electrostatic energy mitigation equipment can include mobile ionizing fan 251. Mobile ionizing fan 251 is mounted on robotic base 253. The robotic base includes a controller and communications interface. Disclosed embodiments can send a sequence of instructions to the mobile ionizing fan and/or robotic base 253 to dispatch the mobile ionizing fan 251 to a specified area within premises 201. In this way, additional mitigation can be automatically performed at multiple areas within the premises 201. Thus, in embodiments, the automatic mitigation action comprises dispatching a mobile ionizing fan to a location within the premises, wherein the location is correlated with elevated electrostatic electricity levels, and activating the mobile ionizing fan.

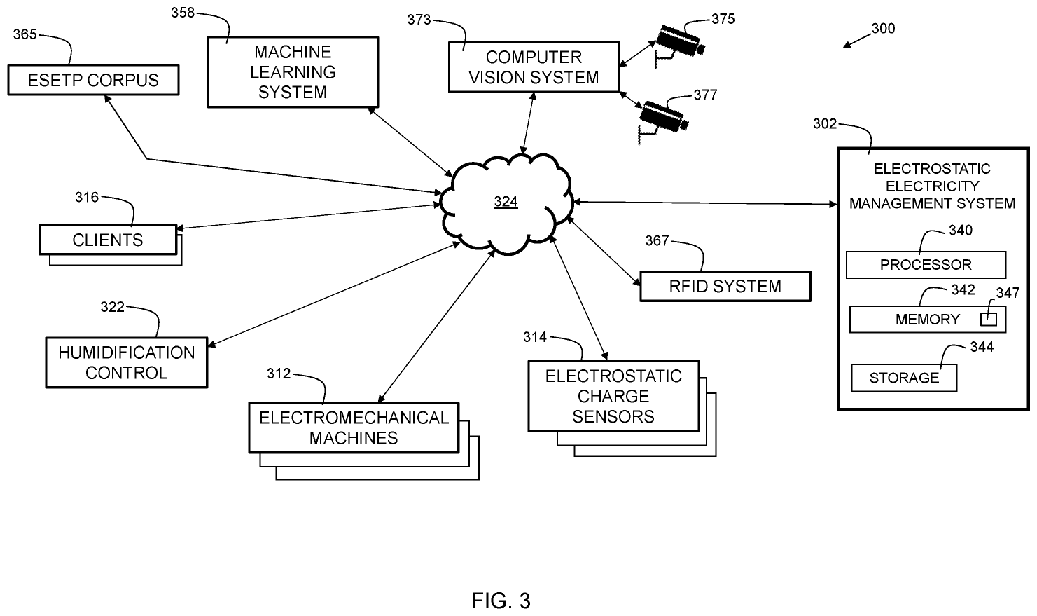

FIG. 3 is an exemplary ecosystem 300 in accordance with disclosed embodiments. Electrostatic Electricity Management System 302 comprises a processor 340, a memory 342 coupled to the processor 340, and storage 344. System 302 is an electronic computation device. The memory 342 contains program instructions 347, that when executed by the processor 340, perform processes, techniques, and implementations of disclosed embodiments. Memory 342 may include dynamic random-access memory (DRAM), static random-access memory (SRAM), magnetic storage, and/or a read only memory such as flash, EEPROM, optical storage, or other suitable memory and should not be construed as being a transitory signal per se. In some embodiments, storage 344 may include one or more magnetic storage devices such as hard disk drives (HDDs). Storage 344 may additionally include one or more solid state drives (SSDs). The Electrostatic Electricity Management System 302 is configured to interact with other elements of ecosystem 300. Electrostatic Electricity Management System 302 is connected to network 324, which can be the Internet, a wide area network, a local area network, and/or other suitable network.

Ecosystem 300 may include one or more client devices, indicated as 316. Client device 316 can include a laptop computer, desktop computer, tablet computer, smartphone, and/or other suitable computing device. Client device 316 may be used to configure Electrostatic Electricity Management System 302, establish ESD mitigation policies, ESD notification policies, input training data, and/or configure/execute other features for disclosed embodiments.

Ecosystem 300 may include humidification control 322. Humidification control 322 may include one or more humidification systems, dehumidifiers, heat pumps, and/or other heating, ventilation, and air conditioning (HVAC) controls and/or machines. In embodiments, humidification control 322 has a communication interface capable of receiving commands from the Electrostatic Electricity Management System 302. In some embodiments, a protocol such as Simple Network Management Protocol (SNMP), TR-069, or other suitable management protocol is used for controlling the humidification control 322.

Ecosystem 300 may include one or more electromechanical machines 312. The electromechanical machines can include, but are not limited to, conveyor belts, robotic gantries, pick-and-place machines, saws, lathes, drills, sanders, polishers, vibratory feeders, packaging machines, fork lifts, and/or other electromechanical machines used for a given purpose in a particular fabrication environment. The equipment may be used to fabricate one or more products, parts, and/or intermediate assemblies, but may also be sources of electrostatic electricity. Disclosed embodiments utilize one or more electrostatic charge sensors 314 to monitor the electrostatic electricity and/or potential within a premises. In embodiments, each electrostatic charge sensor communicates with the Electrostatic Electricity Management System 302 via network 324. In embodiments, each of the electrostatic charge sensors 314 includes a communication interface that includes WiFi, Bluetooth, Bluetooth Low Energy (BLE), and/or Ethernet interfaces, such that electrostatic energy data can be transmitted to the Electrostatic Electricity Management System 302. In embodiments, each of the electrostatic charge sensors 314 may send a preamble along with the data. The preamble can include metadata. The metadata can include a unique identifier, such as a MAC address, and/or other identifier that denotes a location within the premises. The preamble can also include a time-of-day, in UTC time, GPS seconds, or other suitable format. In this way, the Electrostatic Electricity Management System 302 has information regarding a location within the premises to which electrostatic electricity/charge data from the sensor pertains.

Some electromechanical machines may generate operational log files that are parsed by the Electrostatic Electricity Management System 302. This can be used to determine a particular activity of an electromechanical machine. As an example, a pick-and-place machine may utilize multiple robotic gantries. The pick-and-place machine may record gantry position data in log files, along with corresponding timestamps. The Electrostatic Electricity Management System 302 may utilize this information to correlate a specific electromechanical machine operation with electrostatic electricity levels detected in the area of that electromechanical machine.

Ecosystem 300 may include machine learning system 358. The machine learning system 358 can include, but is not limited to, a convolutional neural network (CNN), Support Vector Machine (SVM), Decision Tree, Recurrent Neural Network (RNN), Long Short Term Memory Network (LS™), Radial Basis Function Network (RBFN), Multilayer Perceptron (MLP), and/or other suitable neural network type. In embodiments, the machine learning system 358 is trained using supervised learning techniques. Once trained, the machine learning system 358 may be used to predict times of electrostatic electricity/charge that exceeds a predetermined threshold.

Some embodiments may utilize an SVM. The SVM utilizes a supervised machine learning method, which can be used to identify the pattern of electrostatic electricity generation over a time sequence within an activity. This includes training on historical data containing examples of activities and their corresponding electricity generation patterns (for that activity). Disclosed embodiments utilize SVM to find the correlation between different variables like humidity level, temperature, etc. and electrostatic electricity generation in an activity.

Other embodiments can utilize a Decision Tree. In embodiments, the Decision Tree is used to derive the pattern of electrostatic electricity generation within an activity. Decision tree learning is an unsupervised machine learning technique, which can be used to find patterns in the data without having to know what kind of result is required beforehand. As the system has a time history of the activities and their correlation with electrostatic electricity generation, it can be used to derive patterns by feeding historical data into decision trees.

Ecosystem 300 may include computer vision system 373. Computer vision system 373 may be coupled to one or more video cameras. In FIG. 3, two such cameras are shown, indicated as 375 and 377. In practice, there can be more or fewer cameras than shown in FIG. 3. The computer vision system 373 can be used to detect mechanical activity, such as the movement of people and/or machinery. The mechanical activity can be correlated in time and location with detected electrostatic charge from electrostatic charge sensors 314 to create an electrostatic electricity temporospatial pattern (ESETP) of the premises in which the ESETP is based on the obtained measurements and the mechanical activity.

In embodiments, the ESETP comprises a numerical representation of changes in electrostatic electricity levels in time and space. In embodiments, the ESETP can be represented as a set of multidimensional arrays. Each multidimensional array can include a two-dimensional or three-dimensional representation of electrostatic electricity levels within a physical space, such as a factory floor. Each value within the multidimensional array represents a level of electrostatic electricity at a given location or region within the physical space. Each multidimensional array within the set represents a different instance in time. In some embodiments, a new multidimensional array is added to the set at a periodic interval (e.g., every 10 seconds). A multidimensional array can be visualized by creating a two-dimensional and/or three-dimensional rendering of an image. The image can include a pattern, where the pattern is based on values within the multidimensional array. The pattern can be a visualization map, where the pattern is based on a physical area. As an example, levels of elevated electrostatic electricity can be represented in the visualization map with the color red, while levels of reduced electrostatic electricity can be represented in the visualization map with the color green. In an example where the northwest corner of a premises has elevated electrostatic electricity levels while the southeast corner of that premises has reduced levels of electrostatic electricity, the corresponding visualization map can show red in the upper left corner and green in the lower right corner, to correspond to the relative electrostatic electricity levels of the physical premises. In some embodiments, multiple visualization maps can be rendered in sequence to form an animation, where the animation indicates changes in electrostatic electricity levels over time within a premises.

Ecosystem 300 may include ESETP corpus 365. The ESETP corpus can be implemented via a networked database. The ESETP corpus contains information describing electrostatic electricity generation patterns for different activities in the premises, and can be used as a backend for a knowledgebase. The corpus can be used for training of machine learning systems.

Ecosystem 300 may include Radio Frequency Identification (RFID) system 367. The RFID system 367 may be used to track the movement and/or location of people and/or objects within a premises. The premises can include multiple RFID readers. RFID tags can be affixed to people and/or objects. As an example, workers can wear RFID bracelets to track their locations within a premises. RFID tags contain an integrated circuit and an antenna, which are used to transmit data to the RFID reader. The data can indicate the object or person that is associated with a given RFID tag.

In disclosed embodiments, data from the computer vision system 373, RFID system 367, electrostatic charge sensors 314, and log files from one or more electromechanical machines 312 are used to create a detailed assessment of electrostatic electricity levels and/or behavior within a premises. The assessment is dynamic, and is updated frequently as people and/or objects move about the premises, enabling the creation of electrostatic electricity temporospatial patterns that can be used for training machine learning system 358. Once trained, predictions of electrostatic electricity levels based on proposed activities can be generated. Based on the predictions, mitigation steps can be taken prior to the start of the activities, reducing the adverse effects of ESD. This can increase product yield in manufacturing operations, particularly with semiconductors and electronic devices, as well as improving safety conditions in premises that house flammable substances.

In embodiments, the machine learning comprises a SVM, Decision Tree, and/or CNN. In embodiments, obtaining electrostatic electricity measurements comprises obtaining data from a plurality of IoT electrostatic charge sensors. In embodiments, detecting mechanical activity comprises using a computer vision system that receives input data from one or more digital cameras.

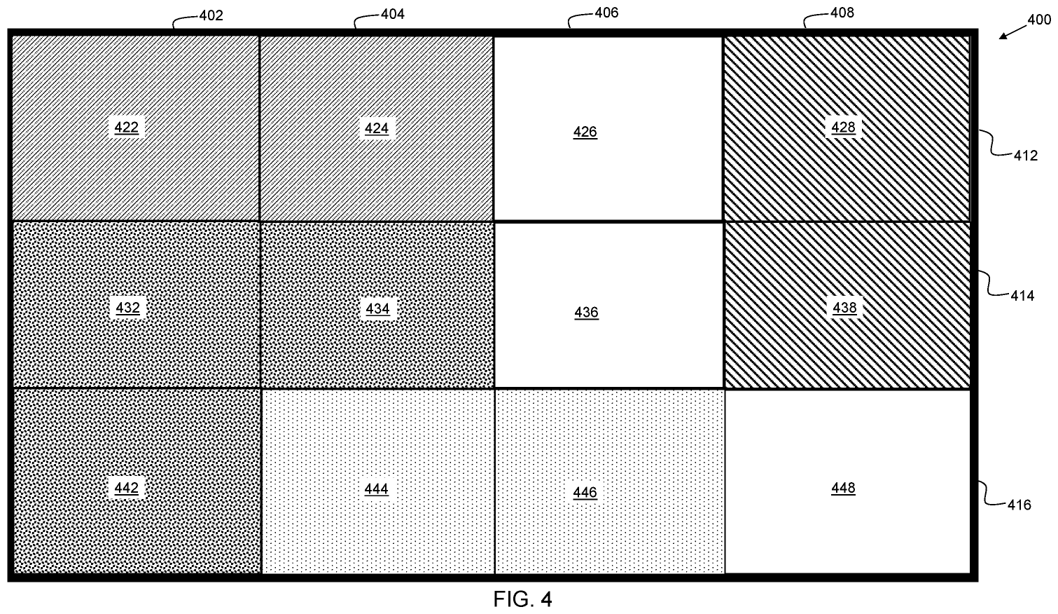

FIG. 4 is an exemplary visualization map 400 in accordance with disclosed embodiments. Visualization map 400 is formed as a grid, having columns 402, 404, 406, and 408, and rows 412, 414, and 416. While visualization map 400 is shown as a 3×4 grid (three rows, four columns), in practice, the visualization map may have a much higher resolution, such as 1920×1080, or other high resolution. The actual resolution may be a function of the capabilities, number, and/or placement of electrostatic charge sensors within the premises.

The visualization map 400 includes multiple regions, indicated as reference numbers 422-448. Each region can also be specified by its row and column. As examples, region 434 is specified by column 404 and row 414, and region 446 is specified by row 406 and column 416. Regions can have different colors and/or patterns to indicate different levels of electrostatic electricity and/or electrostatic potential. As an example, the region 426 may be a region of low electrostatic electricity levels, as compared with that of region 428, which may be a region of comparatively high electrostatic electricity levels. Other patterns, such as those shown in region 422, 432, and 444 may be indicative of intermediate levels of electrostatic electricity. In embodiments, the visualization map 400 can update in real-time as the electrostatic charge sensors 314 detect varying levels of electrostatic electricity/potential. Embodiments can include creating an electrostatic electricity temporospatial pattern (ESETP) of the premises. Embodiments can include generating a visualization map.

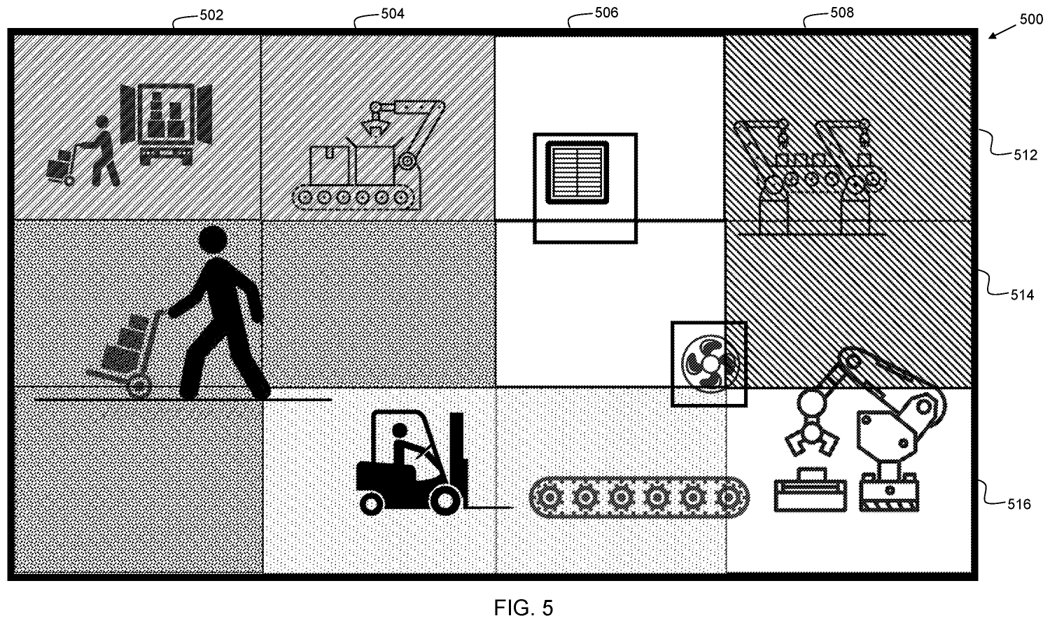

FIG. 5 is an exemplary visualization map overlay 500 in accordance with disclosed embodiments. Visualization map overlay 500 is formed as a grid, having columns 502, 504, 506, and 508, and rows 512, 514, and 516. The visualization map is rendered with a level of transparency such that a representation of the premises can be seen behind the grid. In embodiments, the representation of the premises can be a schematic or floorplan. In some embodiments, the representation of the premises can include live video feeds from one or more cameras within the premises. The visualization map overlay shows correlations of electrostatic electricity data to mechanical activity. As an example, a region at row 514 column 502 can be shaded or colored in a way to designate an elevated level of electrostatic electricity, while a region at row 512 and column 506 can be shaded or colored in a way to designate a reduced level of electrostatic electricity. By using translucency, the visualization map overlay shows the mechanical activity (refer to FIG. 2) associated with the levels of electrostatic electricity. The visualization map overlay allows for a quick and accurate assessment of electrostatic electricity levels within the premises. Embodiments can include performing an overlay of the visualization map with a layout of the premises.

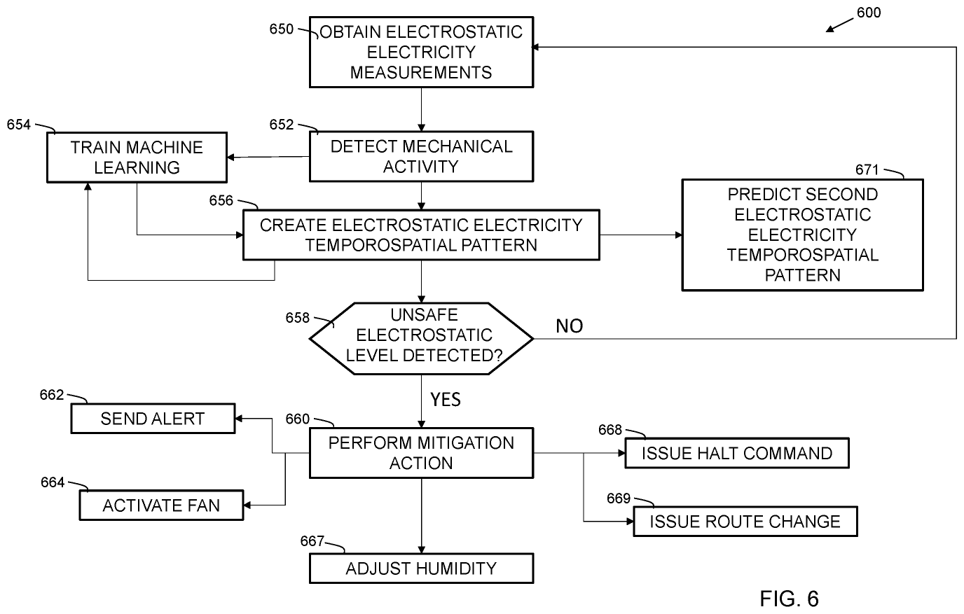

FIG. 6 is a flowchart 600 indicating process steps for disclosed embodiments. At 650, electrostatic electricity measurements are obtained from one or more electrostatic charge sensors. In some embodiments, the electrostatic charge sensors can measure electrostatic potential ranging from 500V to 20 KV. At 652, mechanical activity is detected. The mechanical activity can include operation of machinery, such as conveyor belts, robotic gantries, fork lifts, and/or other machines. The mechanical activity can include human-based activity such as walking, sweeping, pushing a hand cart, and the like. The flow can continue to 654, using the obtained electrostatic electricity measurements and mechanical activity to train a machine learning system. The flow can continue to 656, where an electrostatic electricity temporospatial pattern is created. The electrostatic electricity temporospatial pattern can represent changes in electrostatic electricity levels over a period of time for a given physical location. The flow can continue from 656 back to 654 periodically, where the machine learning system is periodically retrained to learn and adapt to changing conditions, such as new equipment being installed in a premises.

The flow can include predicting a second electrostatic electricity temporospatial pattern 671. As an example, when building a new product, a layout within a factory may change. New equipment may be added, other equipment may be removed, equipment may be moved, etc. Before any actual changes are made, the amount of electrostatic energy that would be generated from those changes can be predicted by utilizing the machine learning system, as well as data from the ESETP corpus (365 of FIG. 3). Embodiments can include predicting a second ESETP within the premises for an activity. In embodiments, the predicting is performed using machine learning, such as by system 358 of FIG. 3.

The flow can include checking for an unsafe electrostatic level 658. The unsafe level can depend on the type of activity occurring in the premises. In embodiments, a predetermined level may be established. The level may be established as a potential using units of volts. As an example, a predetermined level of 1,200 V may be established. When the detected electrostatic electricity levels remain below the predetermined threshold, the flow continues back to 650. When a detected level exceeds the predetermined level, the flow continues to 660, where a mitigation action is performed in response to the detected electrostatic electricity level exceeding the predetermined threshold level. In embodiments, more than one mitigation action may be performed in response to the detected electrostatic electricity/potential level exceeding a predetermined threshold. The mitigation can include adjusting humidity at 667. This can include the Electrostatic Electricity Management System 302 sending messages to the humidification control 322. The mitigation can include issuing a halt command 668, to cause one or more electromechanical machines to stop operation. This can include the Electrostatic Electricity Management System 302 sending messages to the electromechanical machines 312. The mitigation can include activating an ionizing fan 664, to cause the fan to output ionized air, which reduces the risk of an electrostatic discharge event. This can include the Electrostatic Electricity Management System 302 sending messages to ionizing fan 242 and or mobile ionizing fan 251. The mitigation can include sending an alert 662. The alert can be in the form of an email, text message, phone call, audiovisual alert on a dashboard and/or other application, or other suitable alert to stakeholders. The stakeholders can include managers, workers, and/or administrators of the premises. The mitigation can include issuing a route change 669. The route change can be based on a layout of a premises, such as shown in FIG. 2. In embodiments, multiple routes from one point in the premises to another point in the premises are evaluated for electrostatic energy exposure. The route with the least electrostatic energy exposure may identified as a preferred route. In embodiments, the preferred route is sent to a self-driving machine such as an autonomous fork lift. In some embodiments, the preferred route is provided as a recommendation to a user, such as a worker. The worker then can use the recommended route (e.g., walking between two stations within a factory) to reduce his/her exposure to electrostatic electricity.

While the flowchart 600 depicts a particular order of processes, in some embodiments, some processes may be performed in a different order. In some embodiments, some processes may be performed concurrently. In some embodiments, some processes may be omitted.

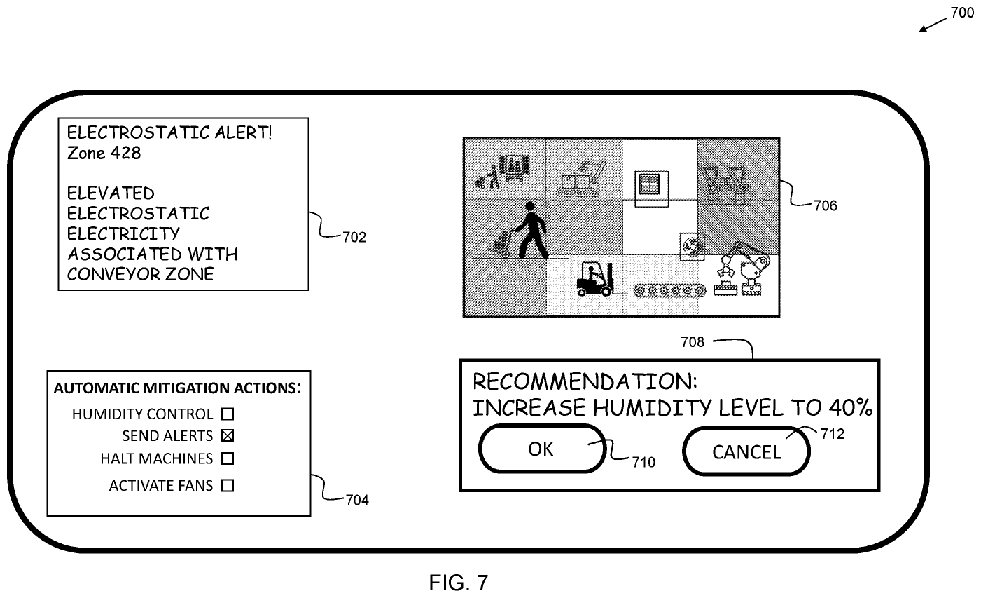

FIG. 7 is an exemplary user interface 700 in accordance with embodiments of the present invention. In embodiments, user interface 700 may be rendered on client device 316 (of FIG. 3) via an HTML browser and/or application (‘app’). User interface 700 includes alert message 702. The alert message 702 can indicate an elevated electrostatic electricity level. The alert can indicate an area or zone within the premises that is experiencing the elevated electrostatic electricity level. The zone can be indicated by a number, alphanumeric designator, and/or name of the zone.

User interface 700 can include a visualization map overlay 706. The visualization map is rendered with a level of transparency such that a representation of the premises can be seen behind the grid. The visualization map overlay may be updated periodically or in real-time, based on data from electrostatic charge sensors within the premises.

User interface 700 can include an automatic mitigation action control 704. This enables an administrator to select one or more actions that can be taken automatically and without human intervention in response to detection of an elevated electrostatic electricity/potential level above a predetermined threshold. Automatic mitigation actions can include, but are not limited to, altering humidity levels, sending alerts, halting machines, and/or activating ionizing fans.

User interface 700 can include an electrostatic electricity mitigation recommendation 708. The recommendation can include a control 710 for accepting the recommendation, and a control 712 for rejecting the recommendation. If a user invokes control 710, it can cause a message to be sent to the Electrostatic Electricity Management System 302 from client device 316, which in turn, executes the instructions and/or sending of messages to carry out the recommendation, such as sending messages to humidification control 322 to adjust the humidity level.

Embodiments can include performing an automatic mitigation action based on a correlation to elevated levels of electrostatic electricity. In embodiments, the automatic mitigation action comprises issuing a halt command to an electromechanical machine within the premises. Embodiments can include sending an alert message via a computer network. In embodiments, the automatic mitigation action comprises adjusting a humidity level within the premises. In some embodiments, the automatic mitigation action comprises activating an ionizing fan within the premises. Embodiments can include generating a recommendation for electrostatic electricity mitigation.

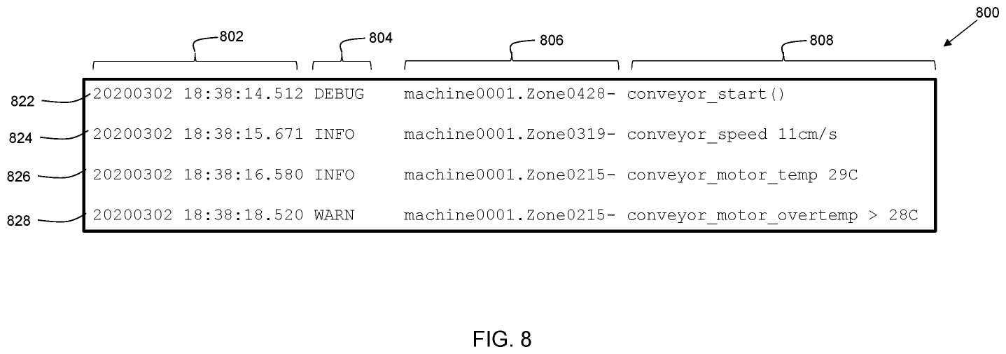

FIG. 8 shows an example 800 of log file analysis in accordance with disclosed embodiments. The log file can be from an electromechanical machine within a premises. The log file can indicate operations of the electromechanical machine. In the example 800, four lines are shown, indicated as 822, 824, 826, and 828. In practice, there can be many thousands of lines within a log file, and each electromechanical machine may produce multiple log files to record its operation. In embodiments, each line has a corresponding timestamp, indicated in column 802. Disclosed embodiments correlate electromechanical machine activity with detected electrostatic electricity/potential levels. In embodiments, each log entry may have a corresponding logging level, indicated in column 804. In some embodiments, to simplify log file parsing and/or analysis, certain logging levels, such as DEBUG, may be ignored. In embodiments, each log file may have a source identifier, indicated at column 806. The source identifier can include unique identification to a specific electromechanical machine, and/or a specific portion of a particular electromechanical machine. This enables disclosed embodiments to infer location information based on the source identifier. In embodiments, each line has a corresponding action, indicated at column 808. This can include text strings that indicate specific operations and/or operating conditions. The text strings can be input to the machine learning system along with corresponding electrostatic electricity levels detected from electrostatic charge sensors within the premises, enabling the machine learning system to identify correlations between machine operations and elevated levels of electrostatic electricity/potential. In embodiments, detecting mechanical activity further comprises parsing operational log data from one or more electromechanical machines within the premises. As an example, an entry in a log file can indicate a conveyor belt operating at a particular speed. A mitigation action may include sending a message to a machine to reduce the conveyor belt speed, which may in turn reduce the electrostatic electricity level. Alternatively, mitigation actions can include dispatching a mobile ionizing fan to a location near the conveyor belt in order to reduce the electrostatic electricity levels in that area, while keeping the conveyor belt speed unchanged. Thus, in embodiments, the automatic mitigation action comprises automatically adjusting a speed of a conveyor belt.

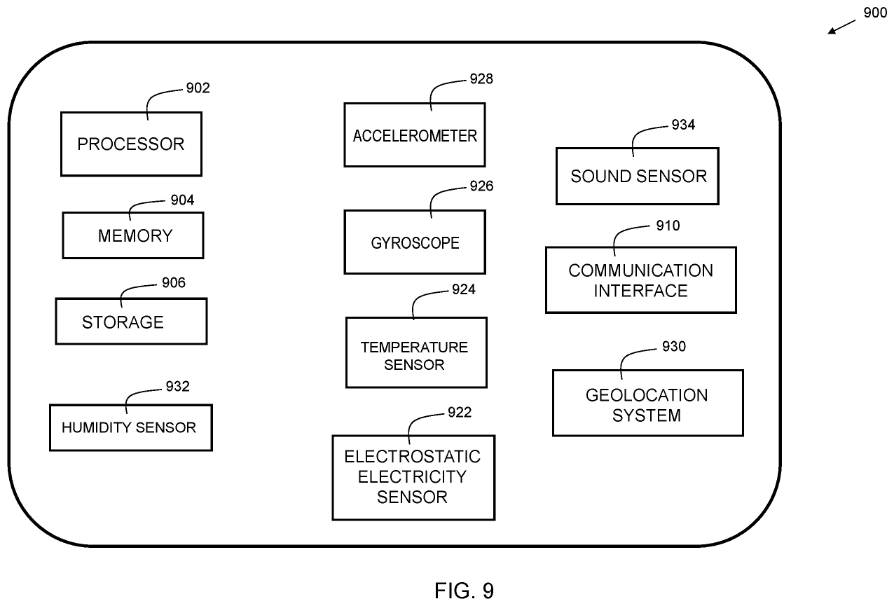

FIG. 9 is a block diagram of a sensor device 900 in accordance with disclosed embodiments. In embodiments, this may represent internal components of an electrostatic charge sensor such as 314 of FIG. 3. Device 900 includes a processor 902, which is coupled to a memory 904. Memory 904 may include dynamic random-access memory (DRAM), static random-access memory (SRAM), magnetic storage, and/or a read only memory such as flash, EEPROM, optical storage, or other suitable memory. The memory 904 should not be construed as being a transitory signal per se.

Device 900 may further include storage 96. In embodiments, storage 906 may include flash, and/or one or more magnetic storage devices such as hard disk drives (HDDs). Storage 906 may additionally include one or more solid state drives (SSDs).

The device 900 further includes a communication interface 910. The communication interface 910 may include a wireless communication interface that includes modulators, demodulators, and antennas for a variety of wireless protocols including, but not limited to, Bluetooth™, Wi-Fi, and/or cellular communication protocols for communication over a computer network and/or operation with an indoor positioning system (IPS) within a premises. In embodiments, instructions are stored in memory 904. The instructions, when executed by the processor 902, cause the electronic computing device 900 to execute operations in accordance with disclosed embodiments.

Device 900 may further include a sound sensor 934 used to receive audio input. The audio input may include sound waves, or noise levels. The audio input may be digitized by circuitry within the device 900. The digitized audio data may be analyzed to determine a pattern. The pattern can be associated with a mechanical activity, such as operation of a machine within the premises.

Device 900 may further include an electrostatic electricity sensor 922 used to measure ambient electrostatic electricity and/or electrostatic potential. The electrostatic electricity sensor 922 may utilize a detection electrode. In some embodiments, the detection electrode can be the gate of a field effect transistor (FET) with an antenna connected thereto. The transistor can be biased such that an electric field exceeding a predetermined level causes a state change in the transistor that is indicative of electrostatic electricity in the vicinity of the antenna. Other techniques for electrostatic energy detection are possible in disclosed embodiments.

Device 900 may further include a temperature sensor 924. The temperature sensor 924 may include a thermoresistor and/or thermocouple for generating an electrical signal corresponding to an ambient temperature. Device 900 may further include a humidity sensor 932. In embodiments, the humidity sensor comprises a capacitive humidity sensor that measures relative humidity utilizing a thin strip of metal oxide positioned between two electrodes. The electrical capacity of the metal oxide changes correspondingly with ambient humidity. Humidity and temperature are important factors in detecting and mitigating conditions of elevated electrostatic electricity. In some embodiments, device 900 may further include geolocation system 930. In embodiments, geolocation system 930 includes a Global Positioning System (GPS), GLONASS, Galileo, or other suitable satellite navigation system.

Device 900 may further include an accelerometer 928 and/or gyroscope 926. The accelerometer 928 and/or gyroscope 926 may be configured and disposed to track movements of an object, such as a crate, fork lift, box, or other object that is moved around within a premises during operations of a facility such as a warehouse and/or factory. In some embodiments, the device may omit one or more elements that are shown in FIG. 9.

Embodiments can further include building a cloud-based shared knowledge corpus, enabling manufacturing sites to share their found best practices through a shared database of like experiences based on the type of manufacturing and business processes involved. Thus, through a shared crowdsourced knowledge corpus, manufacturing processes and business methods can be shared for increasing safety and reducing risk of any electrical shock issues. The data ownership can be anonymized to protect any personal, employee, or private business data or metadata. In embodiments, the machine learning system is trained via a crowdsourced knowledge corpus, where the crowdsourced knowledge corpus contains information regarding various types of mechanical activities, and the electrostatic electricity levels that correlate with those mechanical activities.

Disclosed embodiments are well-suited for a wide variety of manufacturing and/or industrial applications. In one example, a worker is operating a machine to cut metal. He/she is moving the material from one location to another. While material is moved, static electricity is generated. Disclosed embodiments predict the level of electrostatic (static) electricity generation in different parts of the premises based on mechanical activity and make adjustments to the machines and/or environment so that the worker and/or equipment can be protected. In another example, a worker is pouring liquid into a tank which is being dragged by him/her. The liquid generates electrostatic electricity. While it is being poured into the tank, disclosed embodiments predict how much electrostatic electricity generation will occur in different areas of the premises, and recommend an optimal routing for the worker to minimize his/her exposure to static electricity generation. In yet another example, a worker is working in a material storage facility. During loading and unloading of materials in the storage facility, electrostatic electricity generation can be elevated. The worker can view a visualization map overlay for his/her location to understand the different regions of high and low electrostatic electricity generation. A recommended route for the worker can be computed such that it minimizes the nearby activity around him/her, thereby reducing exposure to elevated electrostatic electricity levels. These are just a few of the possible applications of disclosed embodiments for improving the operation and safety of manufacturing and/or warehouse sites.

As can now be appreciated, disclosed embodiments provide management of electrostatic electricity within a premises. The management can include monitoring, predicting, and/or mitigation of elevated electrostatic electricity levels. The mitigation can include automated actions, as well as recommendations. Thus, disclosed embodiments improve the technical field of electrostatic electricity mitigation.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for electrostatic electricity management within a premises, comprising:
obtaining a measurement for electrostatic charge from a plurality of sensors at a plurality of locations within the premises;
detecting mechanical activity within the premises; and
creating an electrostatic electricity temporospatial pattern (ESETP) of the premises wherein the ESETP is based on the obtained measurements and the mechanical activity.

2. The method of claim 1, further comprising predicting a second ESETP within the premises for an activity.

3. The method of claim 2, wherein the predicting is performed using machine learning.

4. The method of claim 3, wherein the machine learning comprises a Support Vector Machine (SVM).

5. The method of claim 3, wherein the machine learning comprises a Decision Tree.

6. The method of claim 3, wherein the machine learning system is trained via a crowdsourced knowledge corpus.

7. The method of claim 1, further comprising performing an automatic mitigation action based on the ESETP.

8. The method of claim 7, wherein the automatic mitigation action comprises automatically adjusting a speed of a conveyor belt.

9. The method of claim 7, wherein the automatic mitigation action comprises issuing a halt command to an electromechanical machine within the premises.

10. The method of claim 7, wherein the automatic mitigation action comprises sending an alert message via a computer network.

11. The method of claim 7, wherein the automatic mitigation action comprises adjusting a humidity level within the premises.

12. The method of claim 7, wherein the automatic mitigation action comprises activating an ionizing fan within the premises.

13. The method of claim 7, wherein the automatic mitigation action comprises:
dispatching a mobile ionizing fan to a location within the premises, wherein the location is correlated with elevated electrostatic electricity levels; and
activating the mobile ionizing fan.

14. The method of claim 1, further comprising generating a visualization map.

15. The method of claim 14, further comprising performing an overlay of the visualization map with a layout of the premises.

16. The method of claim 1, wherein detecting mechanical activity comprises using a computer vision system that receives input data from one or more digital cameras.

17. The method of claim 1, wherein detecting mechanical activity further comprises parsing operational log data from one or more electromechanical machines within the premises.

18. The method of claim 1, further comprising generating a recommendation for electrostatic electricity mitigation.

19. An electronic computation device comprising:
a processor;
a memory coupled to the processor, the memory containing instructions, that when executed by the processor, cause the electronic computation device to:
obtain a measurement for electrostatic charge from a plurality of sensors at a plurality of locations within a premises;
detect mechanical activity within the premises; and
create an electrostatic electricity temporospatial pattern (ESETP) of the premises wherein the ESETP is based on the obtained measurements and the mechanical activity.

20. A computer program product for an electronic computation device comprising a computer readable storage medium having program instructions embodied therewith, the program instructions executable by a processor to cause the electronic computation device to:
obtain a measurement for electrostatic charge from a plurality of sensors at a plurality of locations within a premises;
detect mechanical activity within the premises; and
create an electrostatic electricity temporospatial pattern (ESETP) of the premises wherein the ESETP is based on the obtained measurements and the mechanical activity.
